(19) United States
(12) Patent Application Publication
(10) Pub. No.: US 2024/0379701 A1
(43) Pub. Date: Nov. 14, 2024

(54) SENSOR PACKAGE STRUCTURE AND PACKAGING METHOD

(71) Applicant: STATS CHIPPAC SEMICONDUCTOR (JIANGYIN) CO., LTD., Wuxi (CN)

(72) Inventors: Jeonghan KIM, Wuxi (CN); Soo Won LEE, Wuxi (CN); Jian XU, Wuxi (CN); Hyoungill MIN, Wuxi (CN); Chuanming TANG, Wuxi (CN)

(73) Assignee: STATS CHIPPAC SEMICONDUCTOR (JIANGYIN) CO., LTD., Wuxi (CN)

(21) Appl. No.: 18/631,295

(22) Filed: Apr. 10, 2024

(30) Foreign Application Priority Data
May 10, 2023 (CN) 202310526235.3

(51) Int. Cl. H01L 27/146; H01L 23/00

(52) U.S. Cl. CPC H01L 27/14618; H01L 27/14683; H01L 24/48; H01L 2224/48227

(57) ABSTRACT

A sensor package structure includes: a substrate; a sensor chip, displayed on the substrate and electrically connected to the substrate, where a light-receiving region is displayed on a surface, facing away from the substrate, of the sensor chip; a first package body, covering the substrate and having a chamber therein, where the light-receiving region of the sensor chip is exposed in the first chamber, and the first package body has a first opening, the first opening being in communication with the first chamber and corresponding to the light-receiving region of the sensor chip; a transparent cover plate, displayed within the first opening, where the transparent cover plate includes a first surface facing towards the first chamber and a second surface facing away from the first surface; and a second package body, displayed on the first package body.

### CROSS-REFERENCE TO RELATED APPLICATION

The present application is filed based upon and claims priority to Chinese Application No. 202310526235.3 filed on May 10, 2023, the entire disclosure of which is incorporated herein by reference for all purposes.

### TECHNICAL FIELD

The present disclosure relates to the technical field of semiconductor packaging, and in particular, relates to a sensor package structure and a packaging method.

### BACKGROUND

Optical sensors conduct measurements in accordance with optical principles, and have such characteristics as non-contact and non-destructive measurements, almost no interference, high-speed transmission, remote measurability, and remote controllability. The optical sensors are widely used in aerospace, aviation, national defense research, information industry, machinery, power, energy, transportation, biology, medicine, and the like fields. At present, the optical sensors mainly include: an optical image sensor, a transmission-type optical sensor, an optical measurement sensor, an optical mouse sensor, a reflection-type optical sensor, and the like.

As for packaging of a conventional optical sensor, electrical connection is implemented typically by mounting a transparent cover plate over a sensor chip. The transparent cover plate is sealed by a first bonding layer such as epoxy resin or adhesives or the like, such that foreign matters such as moisture are prevented from entering the transparent cover plate. However, during testing (for example, reliability testing) of the sensor package structure, the transparent cover plate may be subject to detachment, and consequently the yield of the sensor package structure is degraded.

Therefore, how to improve the yield of the sensor package structure becomes the focus of current research.

### SUMMARY

A technical problem to be solved by the present disclosure is to provide examples of a sensor package structure and a packaging method, which help to prevent a transparent cover plate from detachment, such that the yield of the sensor package structure is improved.

In one aspect, some embodiments of the present disclosure provide a sensor package structure. The sensor package structure includes: a substrate; a sensor chip, arranged on the substrate and electrically connected to the substrate, where a light-receiving region is arranged on a surface, facing away from the substrate, of the sensor chip; a first package body, covering the substrate and having a first chamber therein, where the light-receiving region of the sensor chip is exposed in the first chamber, and the first package body has a first opening, the first opening being in communication with the first chamber and corresponding to the light-receiving region of the sensor chip; a transparent cover plate, arranged within the first opening, where the transparent cover plate includes a first surface facing towards the first chamber and a second surface facing away from the first surface, an edge region of the first surface and/or a side wall of the transparent cover plate being sealingly secured or secured in a sealing manner to the first package body via a first bonding layer; and a second package body, arranged on the first package body and pressed against an edge region of the second surface of the transparent cover plate.

In another aspect, some embodiments of the present disclosure provide a packaging method. The packaging method includes: providing a substrate, where a sensor chip electrically connected to the substrate is arranged on a surface of the substrate, a light-receiving region being arranged on a surface, facing away from the substrate, of the sensor chip; forming a first package body, where the first package body covers the substrate and has a first chamber therein, where the light-receiving region of the sensor chip is exposed in the first chamber, and the first package body has a first opening, the first opening being in communication with the first chamber and corresponding to the light-receiving region of the sensor chip; arranging a transparent cover plate within the first opening, where the transparent cover plate includes a first surface facing towards the first chamber and a second surface facing away from the first surface, an edge region of the first surface and/or a side wall of the transparent cover plate being sealingly secured to the first package body via a first bonding layer; and forming a second package body, where the second package body is arranged on the first package body and is pressed against an edge region of the second surface of the transparent cover plate.

### BRIEF DESCRIPTION OF THE DRAWINGS

For clearer descriptions of the technical solutions according to the embodiments of the present disclosure, hereinafter brief description is given with reference to the accompanying drawings for illustrating the embodiments. Apparently, the accompanying drawings described hereinafter only illustrate some embodiments of the present disclosure, and other accompanying drawings may also be derived by persons of ordinary skill in the art based on these accompanying drawings without any creative effort.

FIG. 1A is a schematic diagram of a conventional sensor package structure;

FIG. 1B is a schematic diagram illustrating a transparent cover plate detaching from a package body in a conventional sensor package structure;

FIG. 2 is a structural diagram of a sensor package structure according to a first embodiment of the present disclosure;

FIG. 3 is a structural diagram of a sensor package structure according to a second embodiment of the present disclosure;

FIG. 4 is a structural diagram of a sensor package structure according to a third embodiment of the present disclosure;

FIG. 5 is a structural diagram of a sensor package structure according to a fourth embodiment of the present disclosure; and

FIG. 6 is a schematic flowchart of steps of a preparation method according to an embodiment of the present disclosure.

### DETAILED DESCRIPTION

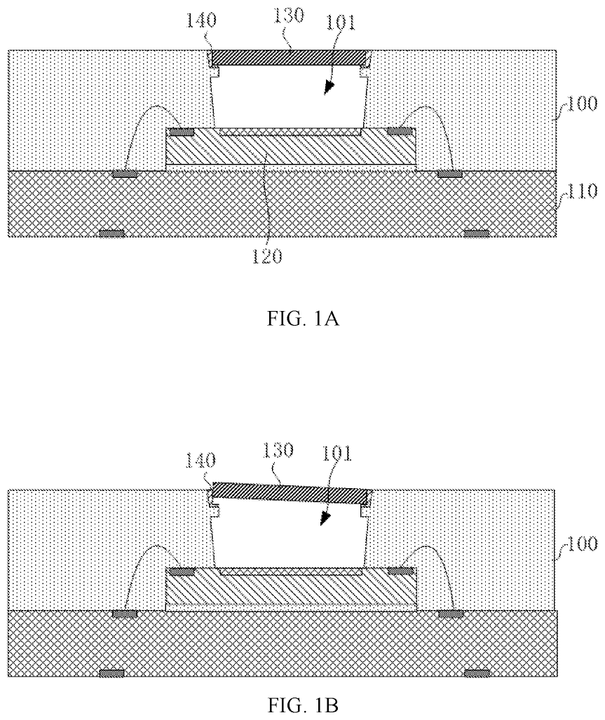

As described in the background, during testing of the sensor package structure, the transparent cover plate may be subject to detachment. Specifically, referring to FIG. 1A, a schematic diagram of a conventional sensor package structure is illustrated. A package body 100 is arranged on a substrate 110, and the package body 100 defines a chamber 101 together with the substrate 110. A sensor chip 120 is arranged on the substrate 110, and is disposed in the chamber 101. A transparent cover plate 130 is arranged over the sensor chip 120, and is attached to the package body 100 via a bonding layer 140. In this way, the sensor chip 120 is transparent and light-transmissive, and sealing protection is achieved for the sensor chip 120. During testing of the sensor package structure, the transparent cover plate 130 is subject to detachment from the package body 100. As illustrated in FIG. 1B, the transparent cover plate 130 detaches from the package body 100, and consequently, damages may be caused to the sensor package structure.

Through study, the inventors have found the cause to the detachment of the transparent cover plate is that during testing of the sensor package structure, the sensor package structure is internally heated and thus a pressure inside the chamber 101 is greater than an adhesive force of the bonding layer 140, and the transparent cover plate 130 detaches from the package body 100 under the effect of the pressure.

Accordingly, some embodiments of the present disclosure provide a sensor package structure and a packaging method, which help to prevent a transparent cover plate from detaching from the first package body, such that the yield of the sensor package structure is improved.

The technical solutions according to the embodiments of the present disclosure are clearly and thoroughly described hereinafter with reference to the accompanying drawings. Obviously, the embodiments described herein are merely exemplary ones, but are not all the embodiments. Based on the embodiments of the present disclosure, all other embodiments derived by persons of ordinary skills in the art without creative efforts shall fall within the protection scope of the present disclosure.

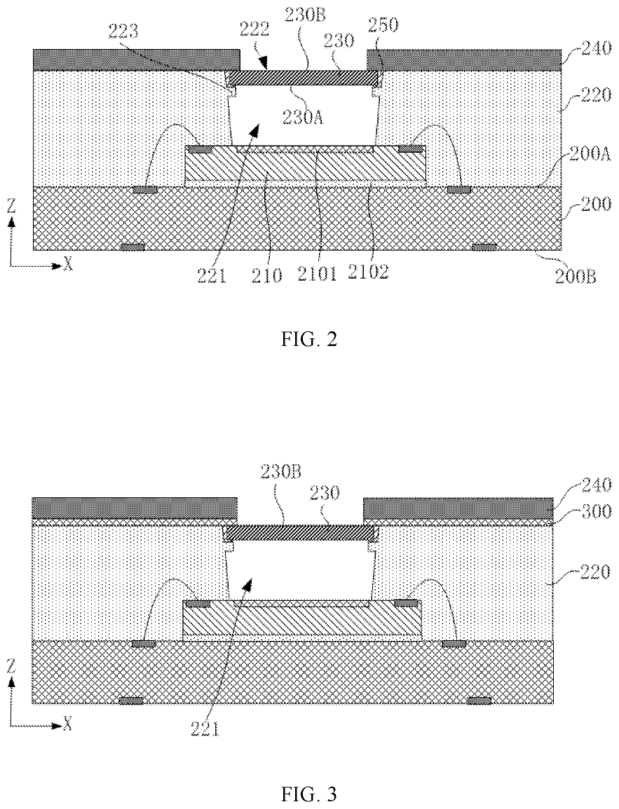

FIG. 2 is a schematic diagram of a sensor package structure according to a first embodiment of the present disclosure. As illustrated in FIG. 2, the sensor package structure includes: a substrate 200, a sensor chip 210, a first package body 220, a transparent cover plate 230, and a second package body 240.

The substrate 200 has an upper surface 200A and a lower surface 200B. The upper surface 200A and the lower surface 200B are opposite to each other. The sensor chip 210 is arranged on the upper surface 200A of the substrate 200. Solder balls or conductive pads may be arranged on the lower surface 200B of the substrate 200 for electrical connection to an external circuit board. The substrate 200 is configured to support the sensor chip 210 and electrically connect the sensor chip 210 to an external circuit board. The substrate 200 includes, but is not limited to, any one of a silicon substrate, a glass substrate, a metal substrate, a semiconductor substrate, a polymer substrate, and a ceramic substrate.

The sensor chip 210 is arranged on the substrate 200 and electrically connected to the substrate 200. A light-receiving region 2101 is arranged on a surface, facing away from the substrate 200, of the sensor chip 210.

In some embodiments, the sensor chip 210 is arranged on the upper surface 200A of the substrate 200, and the conductive interconnect structures are arranged in the substrate 200. The sensor chip 210 is electrically connected to the external circuit board via the conductive interconnect structures. For example, in this embodiment, the sensor chip 210 securely attached to the upper surface 200A of the substrate 200 via a die attach film (DAF) 2102. The sensor chip 210 may also be electrically connected to the substrate 200 via metal wires. In some other embodiments, the sensor chip 210 may also be secured to the upper surface 200A of the substrate 200 via another bonding materials, for example, an adhesive or solders. In some embodiments, the sensor chip 210 may also be electrically connected to the conductive interconnect structure within the substrate 200 via conductive blocks such as solder balls or the like.

The sensor chip 210 is an optical sensor chip 210 and is configured to receive light and implement photoelectric conversion. In some embodiments, the sensor chip 210 includes, but is not limited to, a silicon photonics chip. A light-receiving region 2101 configured to receive light is arranged on a surface, facing away from the substrate 200, of the sensor chip 210.

The first package body 220 covers the substrate 200 and has a chamber 221 therein. The light-receiving region 2101 of the sensor chip 210 is exposed in the first chamber 221. The first package body 220 has a first opening 222. The first opening 222 is in communication with the first chamber 221 and corresponds to the light-receiving region 2101 of the sensor chip 210.

In this embodiment, the first package body 220 is an injection-molded molding body, which covers an upper surface 200A of the substrate 200 by an injection molding process, and covers a side wall and a portion of an upper surface of the sensor chip 210 and forms the first chamber 221 over the light-receiving region 2101 of the sensor chip 210. The light-receiving region 2101 is exposed in the first chamber 221. In a top region of the first chamber 221, the first opening 222 runs through the first package body 220, and is in communication with the first chamber 221.

The transparent cover plate 230 is arranged within the first opening 222. The transparent cover plate 230 includes a first surface 230A facing towards the first chamber 221 and a second surface 230B facing away from the first surface 230A. An edge region of the first surface 230A and/or a side wall of the transparent cover plate 230 is sealingly secured to the first package body 220 via a first bonding layer 250.

Ambient light or returning light pulses passes through the transparent cover plate 230 and is incident into the light-receiving region 2101 of the sensor chip 210 through the first chamber 221. The ambient light includes, but is not limited to, laser, visible light, infrared light, and the like. The transparent cover plate 230 includes, but is not limited to, a glass plate.

In this embodiment, the edge region of the first surface 230A of the transparent cover plate 230 and the side wall of the transparent cover plate 230 are sealingly secured the first package body 220 via the first bonding layer 250, such that sealability and firmness between the transparent cover plate 230 and the first package body 220 are enhanced. The first bonding layer 250 includes, but is not limited to, a DAF or a mounting adhesive. In some other embodiments, only the edge region of the first surface 230A of the transparent cover plate 230 is sealingly secured to the first package body 220 via the first bonding layer 250, such that shield of the transparent region of the transparent cover plate 230 by the first bonding layer 250 is mitigated.

A support step 223 extending towards a center of the first opening 222 is arranged on a side wall of the first opening 222. The edge region of the first surface 230A of the transparent cover plate 230 and/or the side wall of the transparent cover plate 230 is sealingly secured to a surface or a side wall of the support step 223 via the first bonding layer 250. The support step 223 is configured to support the transparent cover plate 230. For example, in this embodiment, the edge region of the first surface 230A of the transparent cover plate 230 and the side wall of the transparent cover plate 230 are sealingly secured to the surface or the side wall of the support step 223 via the first bonding layer 250, and the support step 223 achieves support and securing effects. In some other embodiments, only the side wall of the transparent cover plate 230 is sealingly secured to the side wall of the support step 223 via the first bonding layer 250, the edge region of the first surface 230A of the transparent cover plate 230 is attached to the surface of the support edge 223, and the support step 223 achieves a support effect. In this embodiment, the support step 223 entirely surrounds the first opening 222 along a circumferential direction of the first opening 222, such that the transparent cover plate 230 is further sealingly secured.

The second surface 230B of the transparent cover plate 230 is flush with a surface of the first package body 220, or lower than a surface of the first package body 220. For example, in this embodiment, the second surface 230B of the transparent cover plate 230 is flush with the surface of the first package body 220. In some other embodiments, the second surface 230B of the transparent cover plate 230 is lower than the surface of the first package body 220. That is, in a direction (Z direction in FIG. 2) perpendicular to the surface of the substrate 200, a distance from the second surface 230B of the transparent cover plate 230 to the surface of the first package body 220 at the edge of the first opening 222 is greater than 0, such that the transparent cover plate 230 is protected.

The second package body 240 is arranged on the first package body 220, and is pressed against the edge region of the second surface 230B of the transparent cover plate 230. A region, which is not covered by the second package body 240, of the transparent cover plate 230 is an effective transparent region. The second package body 240 is pressed against the edge region of the second surface 230B of the transparent cover plate 230, such that the transparent cover plate 230 is prevented from moving. In this way, during testing of the sensor package structure, even if the sensor package structure is internally heated and thus a pressure inside the first chamber 221 is greater than an adhesive force of the first bonding layer 250, due to a counteracting force of the second package body 240, the transparent cover plate 230 may not detach from the first package body 220, and hence the yield of the sensor package structure is improved.

The second package body 240 is pressed against a portion or an entirety of the edge region of the second surface 230B of the transparent cover plate 230. For example, in this embodiment, the second package body 240 is pressed against the entirety of the second edge region of the second surface 230B, such that the transparent cover plate 230 is further prevented from detaching from the first package body 220. In some other embodiments, the second package body 240 is pressed against a portion of the edge region of the second surface 230B of the transparent cover plate 230, that is, a portion of the edge region of the second surface 230B of the transparent cover plate 230 is pressed against the second package body 240, and another portion of the edge region is not pressed against the second package body 240, such that a force applied by the second package body 240 against the transparent cover plate 230 is reduced, and the probability that the transparent cover plate 230 breaks due to an excessively great force applied by the second package body 240.

In this embodiment, the second surface 230B of the transparent cover plate 230 is flush with the surface of the first package body 220. In this case, in a surface, facing towards the substrate 200, of the second package body 240, a region corresponding to the first package body 220 is flush with a region corresponding to the transparent cover plate 230. In some other embodiments, the second surface 230B of the transparent cover plate 230 is lower than the surface of the first package body 220, and in this case. In the surface, facing towards the substrate 200, of the second package body 240, the region corresponding to the first package body 220 is higher than the region corresponding to the transparent cover plate 230; or in the surface, facing towards the substrate 200, of the second package body 240, the region corresponding to the first package body 220 is flush with the region corresponding to the transparent cover plate 230, the region corresponding to the transparent cover plate 230 fills the surface of the transparent cover plate 230 via a bonding layer, such that the second package body 240 is capable of effectively pressing against the transparent cover plate 230.

Further, when the side wall of the transparent cover plate 230 is sealingly secured to the first package body 220 via the first bonding layer 250, in the direction (Z direction in FIG. 2) perpendicular to the surface of the substrate 200, an orthographic projection of an overlap region between the second package body 240 and the transparent cover plate 230 on the substrate 200 covers an orthographic projection of the first bonding layer 250 on the substrate 200, such that the press-against effect of the second package body 240 is further enhanced. For example, in this embodiment, the edge region of the first surface 230A of the transparent cover plate 230 and the side wall of the transparent cover plate 230 are sealingly secured to the surface or the side wall of the support step 223 via the first bonding layer 250, and the orthographic projection of the overlap region between the second package body 240 and the transparent cover plate 230 on the substrate 200 covers the orthographic projection of the first bonding layer on the surface and the side wall of the support step 223 on the substrate 200.

In the first embodiment, the second package body 230 is an injection-molded molding body, which covers the surface of the first package body 220 and the edge region of the second surface 230B of the transparent cover plate 230 by an injection molding process, and is securely connected to the first package body 220 and the edge region of the second surface 230B of the transparent cover plate 230. In this way, the first chamber 221 is further sealed.

In some other embodiments, the second package body 240 is a prefabricated frame package body. Specifically, referring to FIG. 3, a schematic diagram of a sensor package structure according to a second embodiment of the present disclosure is illustrated. This embodiment is different from the first embodiment in that in the first embodiment, the first package body 220 and the second package body 240 are both molding bodies formed by injection molding, whereas in the second embodiment, the first package body 220 is an injection-molded molding body but the second package body 240 is a prefabricated frame package body, and the second package body 240 is secured to the first package body 220 and the edge region of the second surface 230B of the transparent cover plate 230 via a second bonding layer 300. The second bonding layer 300 includes, but is not limited to, a DAF or an epoxy resin. In the second embodiment, the second package body 240 is pressed against the transparent cover plate 230, such that the transparent cover plate 230 is prevented from detaching from the first package body 220; and in the meantime, the transparent cover plate 230 is further secured via the second bonding layer 300, such that the first chamber 221 is further sealed.

The present disclosure further provides a third embodiment. The third embodiment is different from the first embodiment in that in the first embodiment, the first package body 220 and the second package body 240 are both molding bodies formed by injection molding, whereas in the third embodiment, the first package body 220 is a prefabricated frame package body and the second package body 240 is an injection-molded molding body.

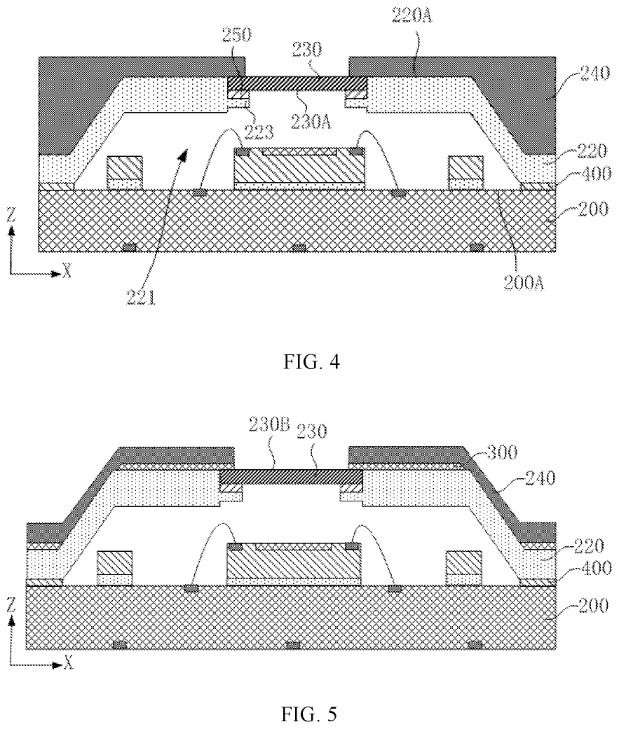

Specifically, referring to FIG. 4, a schematic diagram of a sensor package structure according to a third embodiment of the present disclosure is illustrated. In this embodiment, the first package body 220 is a prefabricated frame package body, which is secured to a portion of the upper surface 200A of the substrate 200 via a third bonding layer 400 and exposes a portion of the upper surface 200A of the first substrate 200, the first package body 220 defines the first chamber 221 together with the exposed upper surface 200A of the first substrate 200, and the sensor chip 210 is arranged on the exposed upper surface 200A of the substrate 200. The third bonding layer 400 includes, but is not limited to, a DAF or an epoxy resin.

In the third embodiment, the upper surface 220A of the first package body 220 has an irregular shape, and the second package body 240 is an injection-molded molding body. In this case, the second package body 240 fills the irregular region of the upper surface 220A of the first package body 220, such that the sensor package structure has a flat outer surface.

In the third embodiment, a support step 223 extending towards a center of the first opening 222 is arranged on a side wall of the first opening 222, where the edge region of the first surface 230A of the transparent cover plate 230 is sealingly secured to a surface of the support step 223 via the first bonding layer 250. In the direction (Z direction in FIG. 3) perpendicular to the surface of the substrate 200, the orthographic projection of the first bonding layer 250 on the substrate 200 covers the orthographic projection of the overlap region between the second package body 240 and the transparent cover plate 230 on the substrate 200. Since the first bonding layer 250 is arranged on the surface of the support step 223, in a direction (X direction in FIG. 3) parallel to the surface of the substrate 200, the support step 223 protrudes from the second package body 240. The support step 223 protruding from the second package body 240 shares the force applied by the second package body 240 against the transparent cover 230, such that a situation where the transparent cover plate 230 breaks due to an excessively great force applied by the second package body 240 against the transparent cover plate 230.

In the third embodiment, a functional chip is arranged on the upper surface of the substrate 200, for example, an ASIC chip. The functional chip is disposed in the first chamber 221, and is electrically connected to the substrate 200 and the sensor chip 220.

The present disclosure further provides a fourth embodiment. The fourth embodiment is different from the third embodiment in that in the third embodiment, the first package body 220 is a prefabricated frame package body but the second package body 240 is an injection-molded molding body, whereas in the fourth embodiment, the first package body 220 is a prefabricated frame package body and the second package body 240 is a prefabricated frame package body.

Specifically, referring to FIG. 5, a schematic diagram of a sensor package structure according to a fourth embodiment of the present disclosure is illustrated. In this embodiment, the second package body 240 is a prefabricated frame package body, which is secured to the first package body 220 and the edge region of the second surface 230B of the transparent cover plate 230 by the second bonding layer 300. In the fourth embodiment, the shape of the second package body 240 may be determined depending on the shape of the first package body 220, such that the second package body 240 is secured to the first package body 220.

In the sensor package structure according to the embodiments of the present disclosure, the transparent cover plate 230 may be prevented from detaching from the first package body 220, such that the yield of the sensor package structure is improved.

In some embodiments, the second surface of the transparent cover plate is flush with a surface of the first package body, or lower than a surface of the first package body.

In some embodiments, the second package body is pressed against a portion or an entirety of the edge region of the second surface of the transparent cover plate.

In some embodiments, a support step extending towards a center of the first opening is arranged on a side wall of the first opening, where the edge region of the first surface of the transparent cover plate and/or the side wall of the transparent cover plate is sealingly secured to a surface or a side wall of the support step via the first bonding layer.

In some embodiments, when the edge region of the first surface of the transparent cover plate is sealingly secured to the first package body via the first bonding layer, in a direction perpendicular to the surface of the substrate, an orthographic projection of the first bonding layer on the substrate covers an orthographic projection of an overlap region between the second package body and the transparent cover plate on the substrate.

In some embodiments, when the side wall of the transparent cover plate is sealingly secured to the first package body via the first bonding layer, in a direction perpendicular to the surface of the substrate, an orthographic projection of an overlap region between the second package body and the transparent cover plate on the substrate covers an orthographic projection of the first bonding layer on the substrate.

In some embodiments, the second package body is an injection-molded molding layer, or a prefabricated frame package body.

In some embodiments, when the second package body is a prefabricated frame package body, the second package body is secured to the first package body and the edge region of the second surface of the transparent cover plate via a second bonding layer.

In some embodiments, the first package body is an injection-molded molding layer, or a prefabricated frame package body.

In the sensor package structure according to the present disclosure, the second package body is pressed against the edge region of the second surface of the transparent cover plate, such that during testing of the sensor package structure, even if the sensor package structure is internally heated and thus a pressure inside the first chamber is greater than an adhesive force of the first bonding layer, due to a press-against effect caused by an counteracting force of the second package body, the transparent cover plate may not detach from the first package body, and hence the yield of the sensor package structure is improved.

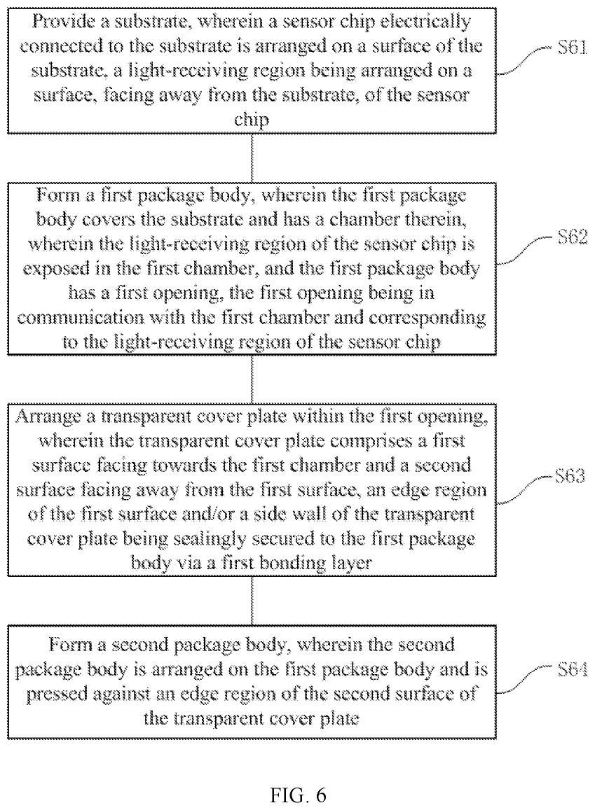

Based on similar technical features, some embodiments of the present disclosure further provide a preparation method for the sensor package structure as described above. FIG. 6 is a schematic flowchart of steps of a preparation method according to an embodiment of the present disclosure. Referring to FIG. 2 to FIG. 6, the method includes the following steps.

In S60, a substrate 200 is provided. A sensor chip 210 electrically connected to the substrate 200 is arranged on a surface of the substrate 200. A light-receiving region 2101 is arranged on a surface, facing away from the substrate 200, of the sensor chip 210.

In some embodiments, the sensor chip 210 is attached to the upper surface 200A of the substrate 200 by a surface mount technology (SMT) process, like wire bonding die attach or flip chip die attach. In addition, the sensor chip 210 is electrically connected to a conductive interconnect structure arranged in the substrate 200 by wire bonding or C4 bump.

In S61, a first package body 220 is formed. The first package body 220 covers the substrate 200 and has a first chamber 221 therein. The light-receiving region 2101 of the sensor chip 210 is exposed in the first chamber 221. The first package body 220 has a first opening 222. The first opening 222 is in communication with the first chamber 221, and corresponds to the light-receiving region 2101 of the sensor chip 210.

In this step, the first package body 220 is formed on the surface of the substrate 200 by injection-molding, as illustrated in FIG. 2 and FIG. 3; or the first package body 220 is a prefabricated frame package body, where the prefabricated frame package body is sealingly secured to the substrate 200 via a third bonding layer 400, as illustrated in FIG. 4 and FIG. 5.

In some embodiments, during forming the first package body 220 on the surface of the substrate 200 by injection molding, the support step 223 extending towards the center of the first opening 222 is formed on the inner wall of the first opening 222; and where the first package body 220 is a prefabricated frame package body, during the prefabrication, a support step 223 extending towards the center of the first opening 222 is formed on the inner wall of the first opening 222.

In S62, a transparent cover plate 230 is arranged within the first opening 222. The transparent cover plate 230 includes a first surface 230A facing towards the first chamber 221 and a second surface 230B facing away from the first surface 230A. An edge region of the first surface 230A and/or a side wall of the transparent cover plate 230 is sealingly secured to the first package body 220 via a first bonding layer 250. The transparent cover plate 230 includes, but is not limited to, a glass plate.

In this step, the first bonding layer 250 may be first formed within the first opening 222 by a process such as dispensing or the like, and then the transparent cover plate 230 is arranged within the first opening 222; and the first bonding layer 250 sealingly secure the transparent cover plate 230 to the first package body 220. In some embodiments, the edge region of the first surface 230A of the transparent cover plate 230 and/or the side wall of the transparent cover plate 230 is sealingly secured to a surface or a side wall of the support step 223 via the first bonding layer 250.

In S63, a second package body 240 is formed. The second package body 240 is arranged on the first package body 220 and is pressed against an edge region of the second surface 230B of the transparent cover plate 230.

In this step, the second package body 240 is formed on the surface of the first package body 220 and the edge region of the second surface 230B of the transparent cover plate 230 by injection molding, and by the injection molding, the second package body 240 having a flat surface is formed and an uneven region of the surface of the first package body 220 is filled, as illustrated in FIG. 2 and FIG. 4; or the second package body 240 is a prefabricated frame package body, the frame package body is secured to the first package body 220 and the edge region of the second surface 230B of the transparent cover plate 230 by the second bonding layer 300, and the shape of the frame package body may be determined depending on the shape of the surface of the first package body 220, as illustrated in FIG. 3 and FIG. 5.

In the preparation method according to the embodiments of the present disclosure, a second package body 240 is formed by secondary package steps. The second package body 240 is pressed against the edge region of the second surface 230B of the transparent cover plate 230, such that the transparent cover plate 230 is prevented from moving. In this way, during testing of the sensor package structure, even if the sensor package structure is internally heated and thus a pressure inside the first chamber 221 is greater than an adhesive force of the first bonding layer 250, due to an counteracting force of the second package body 240, the transparent cover plate 230 may not detach from the first package body 220, and hence the yield of the sensor package structure is improved.

In some embodiments, forming the first package body includes: forming the first package body on the surface of the substrate by injection-molding; or the first package body is a prefabricated frame package body, where the prefabricated frame package body is sealingly secured to the substrate via a third bonding layer.

In some embodiments, forming the second package body includes: forming the second package body on a surface of the first package body and the edge region of the second surface of the transparent cover plate by injection molding; or the second package body is a prefabricated frame package body, where the prefabricated frame package body is secured to the first package body and the edge region of the second surface of the transparent cover plate via a second bonding layer.

Described above are some preferred embodiments of the present disclosure. It should be noted that persons of ordinary skills in the art may derive other improvements or polishing without departing from the principles of the present disclosure. Such improvements and polishing shall fall within the protection scope of the present disclosure.

What is claimed is:

1. A sensor package structure, comprising:
a substrate;
a sensor chip, displayed on the substrate and electrically connected to the substrate, wherein a light-receiving region is displayed on a surface, facing away from the substrate, of the sensor chip;
a first package body, covering the substrate and having a first chamber therein, wherein the light-receiving region of the sensor chip is exposed in the first chamber, and the first package body comprises a first opening, the first opening being in communication with the first chamber and corresponding to the light-receiving region of the sensor chip;
a transparent cover plate, displayed within the first opening, wherein the transparent cover plate comprises a first surface facing towards the first chamber and a second surface facing away from the first surface, an edge region of the first surface or a side wall of the transparent cover plate being secured in a sealing manner to the first package body via a first bonding layer; and
a second package body, displayed on the first package body and pressed against an edge region of the second surface of the transparent cover plate.

2. The sensor package structure according to claim 1, wherein the second surface of the transparent cover plate is flush with a surface of the first package body, or is lower than the surface of the first package body.

3. The sensor package structure according to claim 1, wherein the second package body is pressed against a portion or an entirety of the edge region of the second surface of the transparent cover plate.

4. The sensor package structure according to claim 1, wherein a support step extending towards a center of the first opening is displayed on a side wall of the first opening, and wherein the edge region of the first surface of the transparent cover plate or the side wall of the transparent cover plate is secured in the sealing manner to a surface or a side wall of the support step via the first bonding layer.

5. The sensor package structure according to claim 1, wherein when the edge region of the first surface of the transparent cover plate is secured in the sealing manner to the first package body via the first bonding layer, in a direction perpendicular to a surface of the substrate, an orthographic projection of the first bonding layer on the substrate covers an orthographic projection of an overlap region between the second package body and the transparent cover plate on the substrate.

6. The sensor package structure according to claim 1, wherein when the side wall of the transparent cover plate is secured in the sealing manner to the first package body via the first bonding layer, in a direction perpendicular to a surface of the substrate, an orthographic projection of an overlap region between the second package body and the transparent cover plate on the substrate covers an orthographic projection of the first bonding layer on the substrate.

7. The sensor package structure according to claim 1, wherein the second package body is an injection-molded molding layer, or a prefabricated frame package body.

8. The sensor package structure according to claim 7, wherein when the second package body is a prefabricated frame package body, the second package body is secured to the first package body and the edge region of the second surface of the transparent cover plate via a second bonding layer.

9. The sensor package structure according to claim 1, wherein the first package body is an injection-molded molding layer, or a prefabricated frame package body.

10. A packaging method, comprising:
providing a substrate, wherein a sensor chip electrically connected to the substrate is displayed on a surface of the substrate, a light-receiving region being displayed on a surface, facing away from the substrate, of the sensor chip;
forming a first package body, wherein the first package body covers the substrate and has a first chamber therein, wherein the light-receiving region of the sensor chip is exposed in the first chamber, and the first package body comprises a first opening, the first opening being in communication with the first chamber and corresponding to the light-receiving region of the sensor chip;
arranging a transparent cover plate within the first opening, wherein the transparent cover plate comprises a first surface facing towards the first chamber and a second surface facing away from the first surface, an edge region of the first surface or a side wall of the transparent cover plate being secured in the sealing manner to the first package body via a first bonding layer; and
forming a second package body, wherein the second package body is displayed on the first package body and is pressed against an edge region of the second surface of the transparent cover plate.

11. The packaging method according to claim 10, wherein forming the first package body comprises:
forming the first package body on the surface of the substrate by injection-molding; or
forming the first package body as a prefabricated frame package body, wherein the prefabricated frame package body is secured in a sealing manner to the substrate via a third bonding layer.

12. The packaging method according to claim 10, wherein forming the second package body comprises:
forming the second package body on a surface of the first package body and the edge region of the second surface of the transparent cover plate by injection molding; or
forming the second package body as a prefabricated frame package body, wherein the prefabricated frame package body is secured to the first package body and the edge region of the second surface of the transparent cover plate via a second bonding layer.
